(19) United States
(12) Patent Application Publication
(10) Pub. No.: US 2007/0086256 A1
(43) Pub. Date: Apr. 19, 2007

(54) Optical memory with embedded optical recording medium

(75) Inventors: Jung-wan Ko, Suwon-si (KR); Chong-sam Chung, Hwaseong-si (KR); In-sik Park, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/580,930

(22) Filed: Oct. 16, 2006

(30) Foreign Application Priority Data
Oct. 18, 2005 (KR) 2005-98069

(51) Int. Cl. G11C 13/04

(52) U.S. Cl. 365/215

(57) ABSTRACT

An optical memory includes a substrate and an optical recording layer embedded in a part of the substrate. At least an upper area of the substrate where the optical recording layer is embedded is transparent, and the optical recording layer has a size to read out data recorded in the optical recording layer without using a feeding operation of an objective lens optical system.

### CROSS-REFERENCE TO RELATED APPLICATIONS

This application claims the benefit of Korean Application No. 2005-98069, filed on Oct. 18, 2005 in the Korean Intellectual Property Office, the disclosure of which is incorporated herein by reference.

### BACKGROUND OF THE INVENTION

1. Field of the Invention

Aspects of the present invention relate to an optical memory, and more particularly, to an optical memory in which a very tiny optical recording medium is embedded.

2. Description of the Related Art

As information communication technologies develop rapidly, it is possible to individually carry a recording medium of a relatively small capacity containing recorded information on particular contents such as a credit card information or a transportation card information, and use the recording medium for special purposes. As an example, a credit card or a mass transit ticket is configured to have a magnetic tape coated on a plastic or a paper board. Recently, a recording medium referred to as a smart card, having an embedded semiconductor memory device in a plastic board, has been developed and widely used for a variety of purposes.

However, in the card or ticket having a magnetic tape coating, since reading/writing of the magnetic tape is performed in a contact manner due to the characteristic of the magnetic recording method, the surface of a magnetic tape coating may become damaged or destroyed to cause a malfunction. Also, when a strong magnetic field exists in the vicinity of the card or ticket, data recorded on the magnetic tape coating is likely to be lost.

On the other hand, for an integrated circuit (IC) card in which a semiconductor memory device is embedded, the semiconductor memory device needs to be embedded in a hard plastic board to protect the semiconductor memory device. However, it is disadvantageous to use such an IC card because the IC card is hardly bendable. Also, when the semiconductor memory device is embedded in paper, there is a limit as to how much of the overall thickness of the paper or the semiconductor memory device can be reduced. Accordingly, the flexibility of the IC card is low. To reduce the overall thickness of the IC card, since the size of the semiconductor memory device must also be reduced together, the recording capacity of the semiconductor memory device decreases as well. Furthermore, when the semiconductor memory device is used, the cost per unit of memory increases due to the complexity in the manufacturing process.

### SUMMARY OF THE INVENTION

In view of the above and/or other problems, aspects of the present invention provide an optical memory which has a low possibility of being damaged from careless handling, exhibits superior flexibility, and can be made thin.

Aspects of the present invention provide an optical memory which has a relatively large recording capacity and a low manufacturing cost.

According to an aspect of the present invention, an optical memory includes a substrate and an optical recording layer embedded in a part of the substrate. At least an upper area of the substrate where the optical recording layer is embedded is transparent, and the optical recording layer has a size to read out data recorded in the optical recording layer without using a feeding operation of an objective lens optical system.

A step may be formed around an area where the optical recording layer is embedded such that the area where the optical recording layer is embedded is lower than the other area of the substrate.

The size and thickness of the optical recording layer may be 1-5 mm² and 0.1 mm, respectively.

A mark to determine a reference position for reading out data from the optical recording layer may be formed on the substrate.

The optical recording layer may be a holographic recording medium.

Data may be recorded in the optical recording layer in a recording method of a CD or DVD format.

According to another aspect of the present invention, an optical memory includes a substrate, an optical recording layer attached to a part of the upper surface of the substrate, and a transparent resin layer formed on the optical recording layer. The optical recording layer has a size to read out data recorded in the optical recording layer without using a feeding operation of an objective lens optical system.

According to another aspect of the present invention, an optical memory includes a substrate, an optical recording layer formed in the substrate, and having a non-annular shaped recording area.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the aspects and advantages, taken in conjunction with the accompanying drawings of which:

FIG. 1A is a cross-sectional view of an optical memory according to an aspect of the present invention;

FIG. 1B is a perspective view of the optical memory of FIG. 1A;

FIG. 1C is a plan view of the optical memory of FIG. 1A;

FIG. 2 is a view showing the configuration to read out data from the optical memory of FIG. 1A;

FIG. 3 is a view showing the arrangement state between an image sensor and a holographic recording medium when the holographic recording medium is used as an optical medium according to an aspect of the present invention; and

FIGS. 4A and 4B are views showing examples of reading out data by scanning the optical memory of FIG. 1A.

### DETAILED DESCRIPTION OF THE EMBODIMENTS

Reference will now be made in detail to the aspects of the present invention, examples of which are illustrated in the accompanying drawings, wherein like reference numerals refer to the like elements throughout. The aspects are described below in order to explain the present invention by referring to the figures.

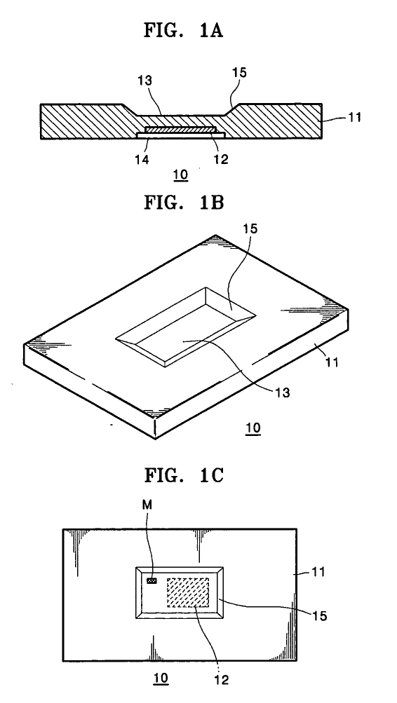

Referring to FIGS. 1A through 1C, an optical memory 10 according to an aspect of the present invention includes a substrate 11 having a thin sheet shape and formed of, for example, paper or plastic, and an optical recording layer 12 formed in a part of the substrate 11. The upper area of the substrate 11 where the optical recording layer 12 is formed is a data reading area 13 which is formed of a transparent material so that light incident on the optical recording layer 12 or reflected from the optical recording layer 12 can pass therethrough. Also, a step portion 15 is formed around the data reading area 13 of the substrate 11 where the optical recording layer 12 is formed. As shown in FIG. 1A, since the data reading area 13 is lower than (or is recessed relative to) the other part of the substrate 11 due to the step portion 15, the possibility of the optical recording layer 12 being abraded or damaged due to physical contact can be reduced. A shape of the data reading area 13 and/or the recessed portion 15 may or may not match various possible shapes of the optical recording layer 12. As shown in FIG. 1C, to determine a reference position to read out the data from the optical recording layer 12, a mark M can be formed on a surface of the substrate 11, or anywhere else, such as the optical recording layer. The mark M may be a sign formed and/or attached at a particular position on the substrate 11 and/or a depressed engraving and/or an engraving in relief to have a predetermined shape, logo, design, and/or features formed on the substrate 11 such as indentations, grooves, cuts, holes, a tiny piece of the optical recording layer 12, or any combination thereof. In a non-limiting example of the present invention, the mark M may even be another optical recording layer, a magnetic layer, a semiconductor device, or any combination thereof.

In other aspects of the present invention, the substrate 11 may be a material having sufficient flexibility and thickness to accommodate the optical recording layer 12. Non-limiting examples of the substrate 11 also include foil, composite, fabric, or the like, or any combination thereof. In other aspects of the present invention, the optical recording layer 12, the data reading area 13, and/or the step portion 15 may be formed in any position of the substrate, in any combination, and in any number. As an example, one group of the optical recording layer 12, the data reading area 13, and the step portion 15 may be formed on one side of the substrate 11 while another group of the optical recording layer 12, the data reading area 13, and the step portion 15 may be formed on an opposite side of the substrate 11. It is understood that both groups may be formed on the same side of the substrate 11.

The method of forming the optical recording layer 12 in the substrate 11 can be performed in a variety of ways. For example, as shown in FIG. 1A, the optical recording layer 12 is coated on a support member 14 and inserted in the substrate 11 to embed the optical recording layer 12 in the substrate 11. Also, the optical recording layer 12 may be attached on the upper surface of the substrate 11 and transparent resin is formed thereon. In other aspects of the present invention, the support 14 may be omitted so that the optical recording layer 12 is formed or embedded directly on or in the substrate 11. In other aspects of the present invention, the support 14 may replace the substrate 11 entirely or partially. If the substrate 11 is replaced, the support 14 may be flexible, and may have the data reading area 13 and/or the step area 15 formed on the support 14. If so, the optical recording layer 12 may be formed in the support 14 at the data reading area 13. In this aspect, the resin may be formed over the optical recording layer 12 formed in the support 14. Although shown as being flat or planar in the substrate 11 in FIGS. 1A-1C, the optical recording layer 12 and/or the support 14 may be non-planar, such as being curved, angled, cupped, waved, or any other forms, and may be positioned diagonally or angled in the thickness of the substrate 11.

The optical recording layer 12, for example, can be formed of the same material as that used for a recording layer of a CD or DVD. For example, the optical recording layer 12 can be formed by a coating of a cyanine-based pigment, a phthalocyanine-based pigment, or an azo-based pigment. In this case, data is recorded in the optical recording layer 12 in a recording method for a CD or DVD format. In other aspects of the present invention, a holographic recording medium can be used as the optical recording layer 12. The holographic recording medium adopts a method of recording data by forming a three dimensional interference pattern using a laser on a photosensitive material. When the same material as that used in a recording layer of a CD or DVD is used, the optical recording layer 12 may contain pits that indicate data, or may be a phase-change material wherein melted portions of the phase-change material indicate data. Although not required in all aspects of the present invention, none, some portion, or the entire portion of the optical recording layer 12 may be non-rewriteable, while any remaining portion may be re-writeable. In various aspects of the present invention, portions of the optical recording layer 12 that contain permanent data may be non-rewritable, while portions of the optical recording layer 12 that contain non-permanent data may be rewriteable.

In various aspects of the present invention, the optical recording layer 12 may have various shapes and thicknesses. Although not required in all aspects, the optical recording layer 12 has a non-annular shape or an area. As an example, the optical recording layer 12 may be circular or rectangular. Although not required in all aspects, the optical recording layer 12 may have a corresponding shape of the substrate 11.

The optical recording layer 12 has a size sufficient to read out data recorded in the optical recording layer 12 without using a feeding operation of an objective lens optical system. In the objective lens optical system, when data is read out from a CD or DVD disk, the CD or DVD disk is rotated at a high speed while an optical pickup system including the objective lens optical system is fed in the radial direction of the disk. Thus, the structure of such a reproducing apparatus becomes complicated and large and the process of reading out data is inconvenient and lengthy. Since an object of the optical memory 10 according to aspects of the present embodiment is to conveniently read data carried in a magnetic card or an IC card, the data recorded in the optical recording layer 12 must be read out without a complicated feeding operation adapted to the disk by reducing the size of the optical recording layer 12. To this end, in a non-limiting example of the present invention, the size of the optical recording layer 12 has a size of about 1-5 mm² and a thickness of about 0.1 mm or less. However, it is understood that sizes of the optical recording layer 12 greater than 5 mm² and a thickness of greater than 0.1 mm are within the scope of the invention.

Although the size of the optical recording layer 12 may be small, a sufficient amount of recording capacity can be obtained. For example, when the size of the optical recording layer 12 is about 1 mm², the recording capacity when an infrared laser is used for recording is about 32 Kbytes, the recording capacity when a red laser is used for recording is about 128 Kbytes, and the recording capacity when a blue laser is used for recording is about 512 Kbytes. The recording capacity of the optical recording layer 12 will be greater when a shorter wavelength laser is used for recording. It is also understood that the recording capacity of the optical recording layer 12 will be greater when a super-resolution recording layer is used, the super-resolution recording layer being a layer utilizing a super-resolution effect.

Since the thickness of the optical recording layer 12 can be reduced to about 0.1 mm, and considering the fact that the thickness of a sheet of copy paper that is generally used is about 0.1 mm, the optical recording layer 12 can be easily embedded or attached to existing papers. In contrast, and in general, for an IC card having an embedded semiconductor memory device (chip), it is difficult to make the thickness of the IC card thin due to the thickness of a circuit itself including the chip. For the optical memory 10 according to aspects of the present invention, since the thickness of the optical recording layer 12 itself can be formed very thin, the thickness of a card using the optical recording layer 12 can be made thin and there is no serious limit in the material for the substrate 11.

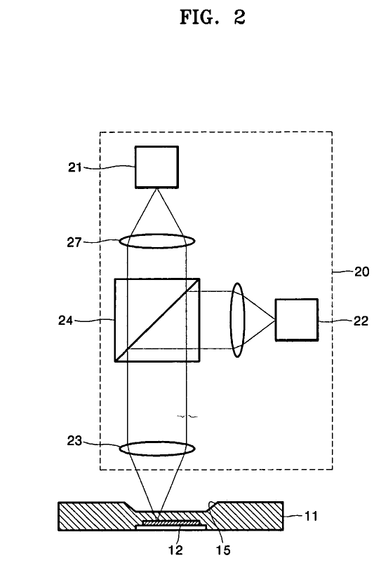

FIG. 2 is a view showing the configuration of a reproduction optical system 20 to read out data from the optical memory of FIG. 1A which uses a recording and/or reproducing method such as one used with a CD or DVD. Referring to FIG. 2, light emitted from a light source 21 such as a laser is changed to a parallel beam by a collimating lens 27, passes through a beam splitter 24, and focused on the optical recording layer 12 by the objective lens 23. The light reflected by the optical recording layer 12 is reflected by the beam splitter 24 and detected by a photodetector 22. As described above, in the aspect of the present invention, since the size of the optical recording layer 12 is small, an apparatus to read out the data from an optical memory according to an aspect of the present invention does not need a transfer servo mechanism to transfer the optical system 20 to an appropriate position on the optical recording layer 12 and a loading mechanism to load the optical memory 10 and fix the same.

In a non-limiting example of the present invention, it is possible to implement the recording and/or reproducing apparatus embodied by the optical system 20 with only a 3D actuator to finely adjust the position of the optical system 20 to accurately focus the laser light on the optical recording layer 12. Thus, like the IC card, by simply drawing the optical memory near the reading apparatus, the data recorded in the optical recording layer 12 of the optical memory 10 can be read.

When the optical recording layer 12 is adopted to be used with a method of recording data in two dimensions like the holographic recording medium, the optical recording layer 12 is formed to have a size of a two dimensional image which can be obtained by radiating the laser beam once. In this case, the recording capacity of the optical recording layer 12 can be around 20 Kbytes.

When the holographic recording medium having the above dimensions or capacity is used as the optical recording layer 12, it is preferable, but not required that the optical recording layer 12 is formed to be circular and an image sensor such as a CCD to read data is correspondingly embodied to be circular.

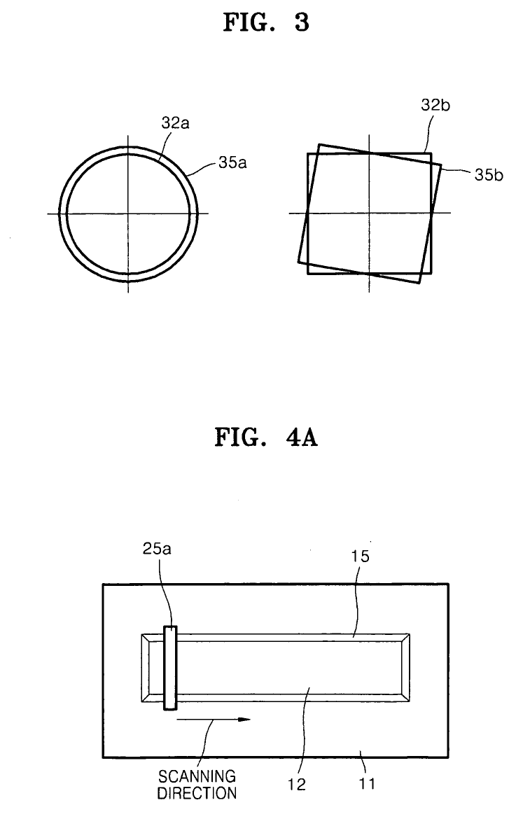

FIG. 3 is a view showing the arrangement state between an image sensor and a holographic recording medium when the holographic recording medium is used as an optical medium according to an aspect of the present invention. When an optical recording layer 32a and an image sensor 35a are formed to be circular, the data can be read out better by arranging the center of the image sensor 35a at the center of the optical recording layer 32a. However, when an optical recording layer 32b and an image sensor 35b are formed to be rectangular, not only the image sensor 35b should be arranged at the center of the optical recording layer 32b, but also a rotation of the image sensor 35b should be compensated. That is, as shown in FIG. 3, when the optical recording layer 32a and the image sensor 35a are circular, the arrangement of the image sensor 35a at the center of the optical recording layer 32a is sufficient. However, when the optical recording layer 32b and the image sensor 35b are rectangular, in addition to the arrangement of the image sensor 35b at the center of the optical recording layer 32b, an additional process of rotating the image sensor 35b relative to the optical recording layer 32b is needed. As described above, when the optical recording layer 12 is a holographic recording medium having a circular shape and a size to read out data by radiating the laser beam once, the data recorded in the optical recording layer 12 of the optical memory can be read out by merely drawing the optical memory near the recording and/or reproducing apparatus.

To further increase a recording capacity of the optical memory 10, the data can be read by sliding the recording and/or reproducing apparatus while the optical memory 10 is fixed, or vice versa. That is, the data can be read by sliding the optical memory 10 with respect to the recording and/or reproducing apparatus that is fixed, or by sliding the recording and/or reproducing apparatus with respect to the optical memory 10. In a non-limiting example of the present invention, such may be done to increase the recording capacity.

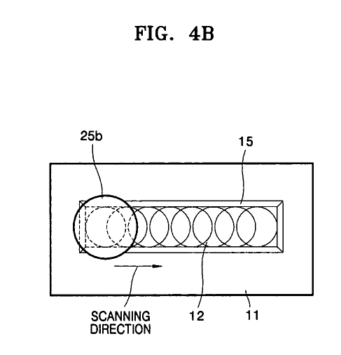

FIGS. 4A and 4B are views showing an example of reading out data by scanning the optical memory of FIG. 1A. As shown, when the data is recorded in the optical recording layer 12 in units of bits as in a typical CD or DVD, a method of reading data while moving a one-dimensional linear image sensor 25a on the optical memory can be used, as shown in FIG. 4A. Also, when a holographic recording medium is used for the optical recording layer 12, as shown in FIG. 4B, while a circular image sensor 25b is moved in a scanning direction, an image that has been multiplexed and recorded on the optical recording layer 12 is read out discretely in separate units of pages to read out the data.

As described above, since the optical memory according to aspects of the present invention has a very small and thin optical recording layer, there are few limitations in selecting a material for the substrate. For example, a substrate exhibiting a strong bending resistance can be manufactured by using a thin and flexible transparent plastic material for the substrate. Also, since the manufacturing method is simple, the optical memory can be manufactured at a low cost. Further, by using the optical recording layer, a relatively large recording capacity can be provided compared to the conventional card type recording medium. Also, the formation of the step portion around the optical recording layer can lessen the possibility of the optical recording layer being damaged during use. The optical recording medium according to the present invention can be used in a variety of fields in diverse forms, for example, as a card such as an IC card or as tags for a product identification purpose instead of barcodes. In various aspects of the present invention, the optical memory including the optical recording medium or the optical recording layer may be used as a tag to be attached to a product and contain information about the product, such as the content of a box. In such a case, a recording and/or reproducing apparatus may be embodied as a scanner that can be a handheld, or a portable device.

Furthermore, a reproduction system for reading out data recorded in the optical memory according to the present invention can reproduce data without the transfer servo mechanism or loading mechanism of a typical CD or DVD. Thus, the reproduction system can be embodied at a low cost.

Although a few aspects of the present invention have been shown and described, it would be appreciated by those skilled in the art that changes may be made in these aspects without departing from the principles and spirit of the invention, the scope of which is defined in the claims and their equivalents.

1. An optical memory comprising:
a substrate; and
an optical recording layer embedded in a part of the substrate,
wherein at least an upper area of the substrate where the optical recording layer is embedded is transparent, and the optical recording layer has a size to read out data recorded in the optical recording layer without using a feeding operation of an objective lens optical system.

2. The optical memory of claim 1, wherein a step is formed around an area where the optical recording layer is embedded such that the area where the optical recording layer is embedded is lower than another area of the substrate.

3. The optical memory of claim 1, wherein the size and thickness of the optical recording layer are 1-5 mm² and 0.1 mm, respectively.

4. The optical memory of claim 1, further comprising a mark to determine a reference position for reading out data from the optical recording layer and formed on the substrate.

5. The optical memory of claim 1, wherein the optical recording layer is a holographic recording medium.

6. The optical memory of claim 1, wherein data is recorded in the optical recording layer in a recording method of a CD or DVD format.

7. An optical memory comprising:
a substrate;
an optical recording layer attached to a part of the upper surface of the substrate; and
a transparent resin layer formed on the optical recording layer,
wherein the optical recording layer has a size to read out data recorded in the optical recording layer without using a feeding operation of an objective lens optical system.

8. The optical memory of claim 7, wherein a step is formed around an area where the optical recording layer is embedded such that the area where the optical recording layer is embedded is lower than another area of the substrate.

9. The optical memory of claim 7, wherein the size and thickness of the optical recording layer are 1-5 mm² and 0.1 mm, respectively.

10. The optical memory of claim 7, further comprising a mark to determine a reference position for reading out data from the optical recording layer and formed on the substrate.

11. The optical memory of claim 7, wherein the optical recording layer is a holographic recording medium.

12. The optical memory of claim 7, wherein data is recorded in the optical recording layer in a recording method of a CD or DVD format.

13. An optical memory, comprising:
a substrate; and
an optical recording layer formed in the substrate, and having a non-annular shaped recording area,
wherein the substrate and the optical recording layer are flexible.

14. The optical memory of claim 13, wherein the optical recording layer is a holographic recording medium.

15. The optical memory of claim 13, further comprising a recessed portion formed on the substrate, wherein the optical recording layer is formed in the recessed portion.

16. The optical memory of claim 13, further comprising a reference marking on at least one of the substrate and the optical recording layer.

17. A tag attachable to a product that includes the optical memory of claim 13.

18. An optical memory, comprising:
a substrate with a recessed portion; and
an optical recording layer formed in the substrate at the recessed portion.

19. The optical memory of claim 18, wherein the substrate comprises a plurality of recessed portions and an optical recording layer is formed at each of the recessed portions.

20. The optical memory of claim 19, wherein at least one of the plurality of recessed portions is formed on one side of the substrate, and at least one of the plurality of recessed portions is formed on an opposite side of the substrate from the one side.
